(19) United States
(12) Patent Application Publication
(10) Pub. No.: US 2002/0114484 A1
(43) Pub. Date: Aug. 22, 2002

(54) Compact narrow band loudspeaker enclosure

(76) Inventors: John D. Crisco, Ellicott City, MD (US); David A. Fitzpatrick, Bel Air, MD (US); Timothy E. Meeks, Belcamp, MD (US)

Correspondence Address: STERNE, KESSLER, GOLDSTEIN & FOX PLLC, 1100 NEW YORK AVENUE, N.W., SUITE 600, WASHINGTON, DC, 20005-3934, US

(21) Appl. No.: 09/753,724

(22) Filed: Jan. 4, 2001

(51) Int. Cl. H05K 5/00; H04R 1/02; H04R 1/20

(52) U.S. Cl. 381/345; 381/346; 381/347; 381/350; 181/148

(57) ABSTRACT

A loudspeaker system design is disclosed. The system includes a driver with a motor structure that is supported by an integrated basket-enclosure. This loudspeaker system reduces the overall size of the enclosure, and increases the efficiency of the design.

### BACKGROUND OF THE INVENTION

1. Field of the Invention

This invention relates generally to the design of a compact loudspeaker enclosure for use in applications requiring high acoustic output while imposing stringent size, weight, reliability and environmental requirements. More specifically, it is related to the design of compact loudspeaker enclosures for use in active noise cancellation systems, and, in particular, for use in an active noise cancellation muffling system for an internal combustion engine.

2. Related Art

For a variety of economic and engineering reasons electro-dynamic transducers composed of a diaphragm driven by a voice-coil immersed in a magnetic field generated by a permanent magnet have become the generally accepted standard for reproducing sound in most applications. This is also true in the field of active noise cancellation (ANC) where such transducers are commonly used to reproduce an acoustic cancellation sound which is essentially an out of phase copy of the undesirable noise signal of equal amplitude. When this additional sound is acoustically combined with the undesirable noise signal, the two signals effectively cancel one another out, a phenomena referred to as acoustic wave cancellation. ANC technology is currently used in a variety of applications, including controlling noise produced by industrial blowers, lowering the noise levels within cabins of aircraft, and reducing the noise levels emitted from exhaust systems of combustion engines.

An enclosure for mounting and tuning the transducer is generally required in order to achieve adequate performance for most applications including active noise cancellation. In ANC muffler systems, an enclosure allows the system to operate more efficiently within the desired response range, and protects it from the elements.

Historically, one of the most difficult problems facing loudspeaker designers has been choosing appropriate trade-offs between enclosure size and acoustical efficiency at lower frequencies. The mathematical relationships between diaphragm size, enclosure volume and acoustic efficiency are well known to those skilled in the art of loudspeaker design. However, in active noise cancellation (ANC) systems, finding an acceptable trade-off between size, efficiency and reliability can be exceptionally difficult. ANC often requires reproduction of very high acoustic levels for long periods of time and frequently requires that the cancellation sound source be placed in close proximity to the source of the noise to be canceled. Since ANC is often added to an existing piece of equipment or installation, this can result in severe limitations on the space available. In addition, ANC systems often operate under hostile environmental conditions which create further difficulty in creating appropriate system designs.

As an example of these conflicting requirements, active noise cancellation has long been considered an attractive approach to reducing the exhaust sound generated by internal combustion engines used in automobiles. ANC has the potential to improve engine efficiency by eliminating the need for conventional restrictive mufflers. However, the acoustic output required to cancel the exhaust noise is quite high while the space available is very limited. Moreover, the noise cancellation sound source is exposed to moisture, mechanical impact and extremes of temperature. Many attempts to design a practical active noise cancellation system for use on automobiles have focused on using band-pass type loudspeaker enclosures.

It is desirable to provide an ANC muffler system incorporated into an automobile offered for sale to the general public. Previous design attempts have failed to achieve adequate performance in one or more of the critical areas of adequate acoustic output, size, reliability, resistance to environmental damage, cost or weight.

### SUMMARY OF THE INVENTION

The present invention offers a method of overcoming these obstacles through the use of a novel acoustic design procedure in combination with a novel integrated basket-enclosure construction method. Disclosed is a new method for designing band-pass systems which allows higher efficiency over a restricted frequency range and further reduction in enclosure size. A band-pass type enclosure offers advantages in efficiency at lower frequencies for a given enclosure size. In addition, since the driver in a band-pass enclosure is mounted internally, it is more easily protected from the environment. Going a step further, this invention takes advantage of the typically small sealed chamber and introduces a novel construction method which increases durability, simplicity and rigidity while decreasing size.

### BRIEF DESCRIPTION OF THE FIGURES

The foregoing and other features and advantages of the invention will be apparent from the following, more particular description of a preferred embodiment of the invention, as illustrated in the accompanying drawings:

FIG. 1 is a cross-sectional view of a typical band-pass type enclosure;

FIG. 2 is a cross-sectional view of the traditional loudspeaker to enclosure mounting method;

FIG. 3 is a detailed view of the traditional loudspeaker to enclosure mounting method of FIG. 2;

FIG. 4 is a cross-sectional view of the pressure plate mounting method disclosed in U.S. Pat. No. 6,005,957 to Meeks;

FIG. 5 is a detailed view of the pressure plate mounting method of FIG. 4;

FIG. 6 is a cross-sectional view of the loudspeaker enclosure of the present invention utilizing an integrated basket-enclosure and a spider ring;

FIG. 7 is a detailed view of the loudspeaker enclosure of FIG. 6;

FIG. 8 is an exploded view of an alternate embodiment of the loudspeaker enclosure of the present invention, including a front enclosure and a port grill;

FIG. 9 is a cross-sectional view of an alternate embodiment of the loudspeaker enclosure of the present invention depicting a motor structure mounted to the exterior of an enclosure;

FIG. 10 is a graph depicting the frequency response of an illustrative enclosure design using the method disclosed in U.S. Pat. No. 5,474,764 to Polk;

FIG. 11 is a graph depicting the frequency response of an illustrative enclosure design using the method of the present invention; and

FIG. 12 is a bottom view of the integrated basket-enclosure of FIG. 6.

### DETAILED DESCRIPTION OF THE PREFERRED EMBODIMENTS

A preferred embodiment of the present invention is now described with reference to the figures where like reference numbers indicate identical or functionally similar elements. Also in the figures, the left most digit of each reference number corresponds to the figure in which the reference number is first used. While specific configurations and arrangements are discussed, it should be understood that this is done for illustrative purposes only. A person skilled in the relevant art will recognize that other configurations and arrangements can be used without departing from the spirit and scope of the invention. It will be apparent to a person skilled in the relevant art that this invention can also be employed in a variety of other devices and applications.

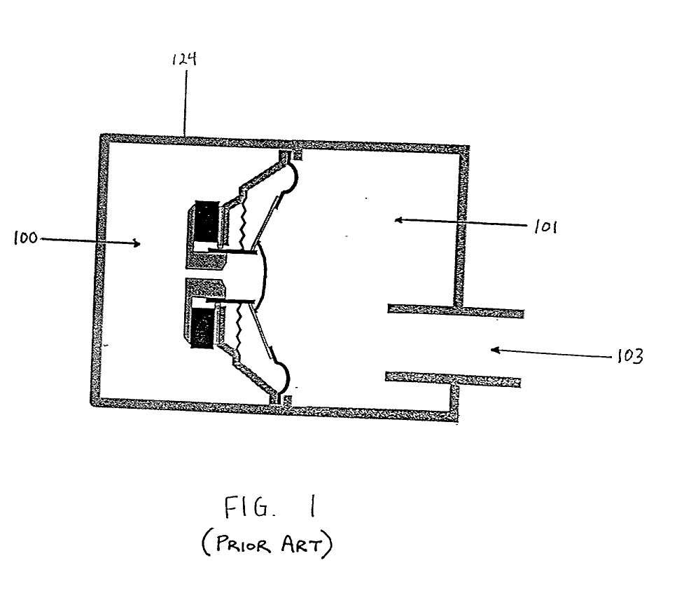

As discussed above, loudspeaker enclosures can be made smaller by sacrificing acoustic efficiency. Lower acoustical efficiency means that more electrical power is required to achieve a specified sound output. Typically band-pass type systems, such as the band-pass type system shown in FIG. 1 which includes an enclosure 124 with a sealed chamber 100, a vented chamber 101 and a passive radiating port 103, are designed to provide both the best combination of acoustical efficiency and wide bandwidth for a given enclosure size. It is well known to those skilled in the art that for a single ended band-pass type system, an optimum relationship of enclosure size and overall efficiency is obtained for systems with a bandwidth of approximately 1.5 octaves.

U.S. Pat. No. 5,475,764 to Polk, which is incorporated herein by reference in its entirety, discloses a method for designing band-pass type low frequency loudspeaker systems including an enclosure having a partition dividing it into a first and a second chamber. The first chamber is sealed, and the second chamber has a passive radiating element, port or vent communicating with air outside the enclosure.

A transducer converts an input signal to an output signal. In a loudspeaker system, the loudspeaker is a device wherein electrical signal energy is converted into acoustical energy, and a driver is the portion of the loudspeaker system that converts the electrical energy into acoustical energy. In the method described in U.S. Pat. No. 5,475,764, a driver which is a transducer of the type having a diaphragm with front and rear sides is mounted in the partition.

The system is based on three ratios:

$$Qmc ≡ \frac{Mmd \cdot fc}{kg \cdot {sec}^{- 1}} Qtc ≡ {( \frac{MAS}{CAT} )}^{.5} \cdot \frac{1}{R0}$$

$$Qtp ≡ {( \frac{MAP2}{CA2} )}^{.5} \cdot \frac{1}{R0}$$

where

Eg=amplifier output voltage

Rg=amplifier source voltage

B1=driver motor force factor

Re=driver voice-coil DC resistance

Sd=driver diaphragm area

Mmd=moving mass of the driver in kilograms

Cms=compliance of driver suspension

Rms=mechanical loss of driver

V1=volume of sealed chamber

V2=volume of vented chamber

Sp2=cross-sectional area of port

t2=length of port

fs=free-air resonance of driver

fc=resonance of the driver in a sealed cavity

fp=resonance of port mass against vented chamber

CAT=combined acoustic compliance of driver suspension and sealed cavity

MAS=acoustic moving mass of driver

RAS=acoustic mechanical loss of driver

CA2=acoustic compliance of vented cavity

MAP2=acoustic mass of vent

R0=acoustic resistance of the voice coil is defined as:

R0=[(B1²/Sd²)/(Rg+Re)]

Regardless of center frequency or size, a system with values of Qtc and Qtp approximately equal to 1.0 and fc=fp will have a bandwidth of approximately 1.5 octaves and an optimal relationship of enclosure size to overall acoustical efficiency, where fc is the resonant frequency of the transducer in combination with the sealed volume and fp is the resonant frequency of the port in combination with the vented volume. If these values for Qtc, Qtp, fc and fp are held constant, the size of the enclosure and all other system parameters can be determined by varying the ratio Qmc while the bandwidth and center frequency of the response remain unchanged. In general, larger values of the ratio Qmc correspond to smaller enclosures and lower acoustical efficiency.

In theory, the method of U.S. Pat. No. 5,475,764 can be used to design a system with an enclosure of arbitrarily small size and optimal efficiency while maintaining the optimal bandwidth of approximately 1.5 octaves. However, at some point the enclosure size becomes so small that the transducer size and port size physically interfere with the enclosure. Finally, the low efficiency of very small enclosures, even when optimally designed, further limits the practicality of such designs either because mechanical limitations prevent the system from producing enough acoustic output or the heat generated by high power consumption compromises system reliability.

U.S. Pat. No. 5,475,764 focuses on maintaining a bandwidth of approximately 1.5 octaves, which offers an optimal relationship of bandwidth and efficiency for any given enclosure size. This relationship is achieved by holding Qtc and Qtp approximately equal to one. The present invention recognizes that many ANC applications require a cancellation sound only over a narrow bandwidth, often much less than 1.5 octaves. The present invention uses a modification of the design technique disclosed in U.S. Pat. No. 5,475,764 to design band-pass enclosures which efficiently trades narrower bandwidth for greater acoustic efficiency and smaller enclosure size.

For example, a particular ANC application could require acoustic output of approximately 115 db SPL (sound pressure level) at 1 meter in a narrow frequency range from approximately 110 Hz to 150 Hz. Using the method described in U.S. Pat. No. 5,475,764 produces a band-pass design with the following parameters and frequency response (2.83 volts input, output predicted at distance of 1 meter):

### EXAMPLE 1

### (U.S. Pat. No. 5,475,764)

| | |
|---|---|
| Internal Driver | Port |
| Bl₁ = 5.359 weber · m⁻¹Cms₁ ≡.00115 m · newton⁻¹ | ${( \frac{Sp2}{π} )}^{.5} \cdot 2 = 2.58 in$ |
| Sd₁ ≡ 0.141 m² | Sp2 ≡ Sp2₂ |
| Re₁ ≡ 2.03 ohm | t2₁ = 8.451 in |
| Mmd₁ = 0.016 kg | fp₁ ≡ 126 Hz |
| fs₁ = 35.58 Hz | Cabinet |
| Rms₁ ≡ .515 kg · sec⁻¹ | |
| Qms₁ = 7.136 | V1₁ = 0.096 ft³ Sealed |
| Qt₁ = 0.965 | V2₁ = 0.088 ft³ Vented |
| fc₁ ≡ 124.719 Hz | |
| Tuning Ratios | |
| Qtc₁ = 1.0 | |
| mc₁ ≡ 2.05 | |
| Qtp₁ ≡ 1.0 | |

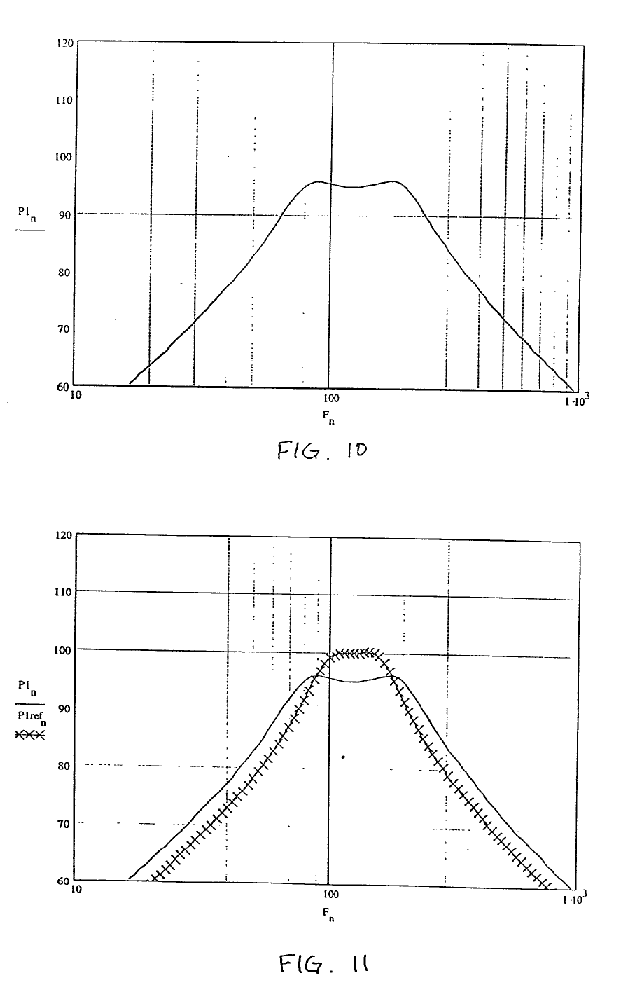

The frequency response of the above described enclosure design using the method described in U.S. Pat. No. 5,475,764 is shown graphically in FIG. 10. However, in accordance with the present invention, the tuning ratios method disclosed in U.S. Pat. No. 5,475,764 is modified to produce a design which is better suited to a narrow bandwidth application by departing from the recommended range of values for the tuning ratios as follows:

### EXAMPLE 2

| | |
|---|---|
| Internal Driver | Port |
| Bl₂ = 6.31 weber · m⁻¹Cms₂ ≡ .00115 m · newton⁻¹ | ${( \frac{{Sp2}_{2}}{π} )}^{.5} \cdot 2 = 2.58 in$ |
| Sd₂ ≡ 0.141 m² | Sp2₂ ≡ π · 1.29² in² |
| Re₂ ≡ 2.03 ohm | t2₂ = 5.0 in |
| Mmd₂ = 0.016 kg | fp₂ ≡ 126.106 Hz |
| fsr₂ = 25.856 Hz | Cabinet |
| Rms₂ ≡ 0.515 kg · sec⁻¹ | |
| Qms₂ = 10.391 | V1₂ = 0.5 ft³ Sealed |
| Qtr₂ = 1.305 | V2₂ = 133 ft³ Vented |
| fcr₂ ≡ 124.393 Hz | |
| Tuninig Ratios | |
| Qtc₂ ≡ 1.339 | |
| Qmc₂ ≡ 3.979 | |
| Qtp₂ ≡ 0.476 | |

The frequency response of this new design in accordance with the present invention is shown by the line crossed with X in FIG. 11, and is compared with the initial enclosure design shown in FIG. 10. As can be seen, the values of Qtc and Qtp have been manipulated outside of the range recommended in U.S. Pat. No. 5,475,764. In addition, Qmc has been increased to produce a design with the same total enclosure volume as the initial design. The new design is unusual in many respects. Although the initial design uses the optimum relationship of bandwidth, efficiency and enclosure size specified in U.S. Pat. No. 5,475,764, the new design has the same total enclosure volume and the same center frequency but with a significant improvement in acoustical efficiency over the range of interest. It can be shown that the new design will produce the required acoustic output of 115 db SPL at 1 meter at the frequencies of 110 Hz and 150 Hz with approximately 135 watts of input power as compared to more than 380 watts for the initial design. The new design allocates much more of the total enclosure volume to the vented chamber giving the new design an unusually lopsided ratio of vented enclosure volume to sealed enclosure volume. This leads to reduced port dimensions while maintaining the same tuning frequency which makes it easier to accommodate the port size in the physical enclosure design.

The improved efficiency of the new design is achieved at the cost of a narrower bandwidth. There has been little interest in narrow bandwidth designs or in developing effective narrow bandwidth design methods. This is due to the requirement for broader bandwidth in the most popular applications, including music and movie sound reproduction. As a result, a great deal of effort has been made to create standard alignments which offer the broadest possible bandwidth for the smallest compromise in efficiency. A typical design process for a band-pass system consists of choosing a generic set of transducer parameters and using the design ratios for a standard alignment to calculate the enclosure parameters and other system parameters. This method allows the designer to quickly arrive at a design which offers the well known performance characteristics of the chosen standard alignment.

The present invention modifies the tuning ratios of U.S. Pat. No. 5,475,764 to optimize the design of reduced bandwidth band-pass systems.

In general, smaller values of Qtp correspond to narrower bandwidths, and the most desirable combination of efficiency and smooth response for a given bandwidth is obtained when the product of Qtp multiplied by Qtc falls in the range of 0.5 to 0.7. Within this range, the bandwidth in octaves between 3 db down points is approximately equal to 1.9 times the value of Qtp.

As discussed above, the allocation of total enclosure volume between the vented and the sealed chambers for the preferred system designs is somewhat lopsided with substantially more volume being allocated to the vented chamber. Such reduction of the volume of the sealed chamber facilitates the novel construction design of the present invention.

The second portion of the present invention is a novel approach to constructing acoustic designs which result from the method already disclosed herein. The advantages of this new construction approach include better heat dissipation, part reduction and simplicity, a more rigid motor mounting scheme, and reduced size.

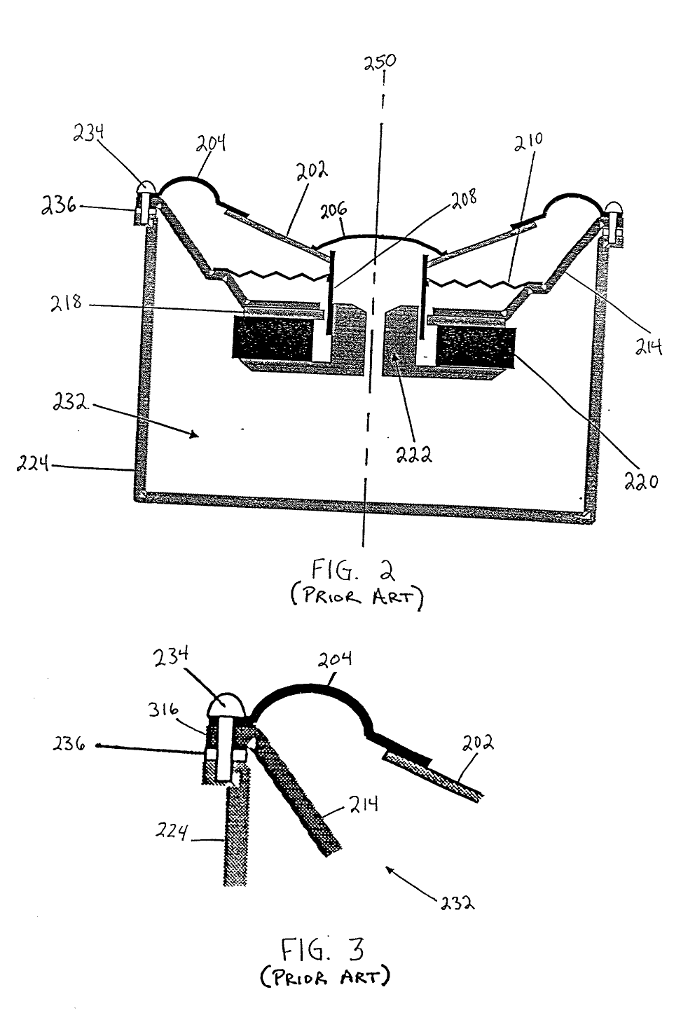

Although size reduction is the least significant advantage to this new construction method, its explanation makes a good introduction to the details of the design. In discussing size, the first dimension to be addressed is the maximum radial breadth from the loudspeaker axis of motion 250 in FIG. 2. For a cylindrical loudspeaker system, this dimension can be described as an outer diameter. In a cylindrical loudspeaker system having a cylindrical enclosure, the minimum enclosure diameter is determined by the amount of functionality required outside of the diaphragm area. Reducing the amount of functionality at this interface will indeed reduce the overall size of the enclosure. In previous loudspeaker enclosure designs, a transducer and a rear enclosure have been designed as separate entities, requiring a means of attachment, such as the traditional loudspeaker to enclosure mounting method shown in FIG. 2, and shown in further detail in FIG. 3. The loudspeaker enclosure design shown in FIG. 2 includes a transducer comprising a transducer diaphragm 202; a diaphragm suspension 204; a dust cap 206; a voice coil 208; a damper 210; a basket 214; and a motor structure including a front ring 218, a magnet 220, and a pole piece 222. The loudspeaker enclosure design shown in FIG. 2 further includes an enclosure 224, a rear air cavity 232, a loudspeaker fastener 234, and a loudspeaker gasket 236. In the system shown in FIGS. 2 and 3, diaphragm suspension 204 is glued to basket 214, and basket 214 is screw fastened to enclosure 224 by fasteners 234 around the perimeter of basket 214. This mating area on basket 214 is a flange 316, as shown in FIG. 3, and it mates to a face of enclosure 224 that has a hole of similar shape (typically circular). This method requires flange 316 to provide two mating functions: (1) to provide sufficient surface area for a compression-type air seal, and (2) to provide sufficient surface area for thru-hole fasteners 234. Both of these functions pose constraints on how small the flange can be.

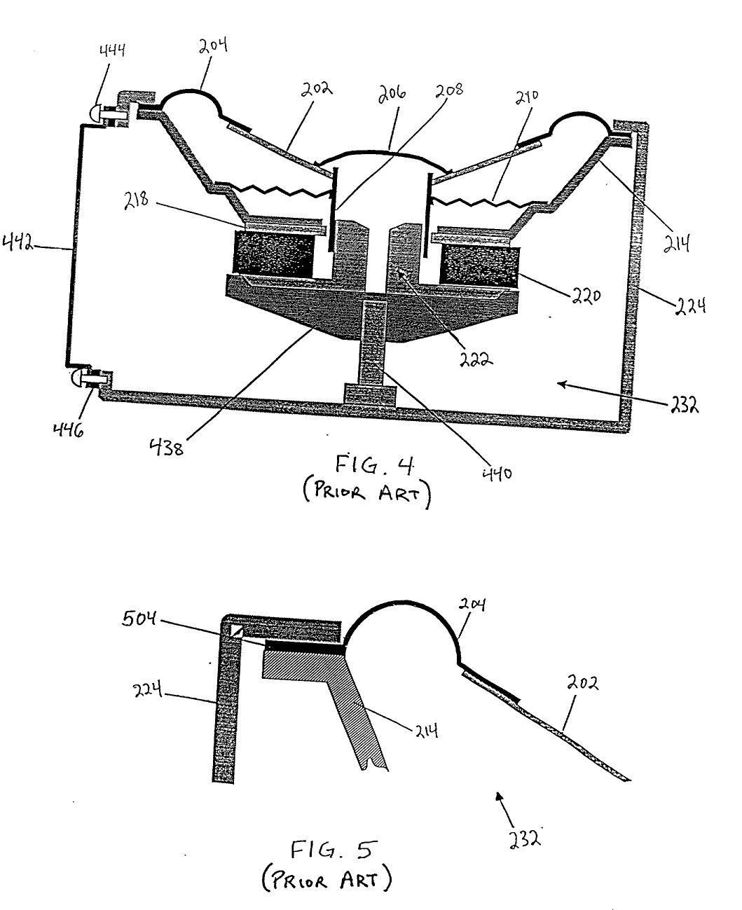

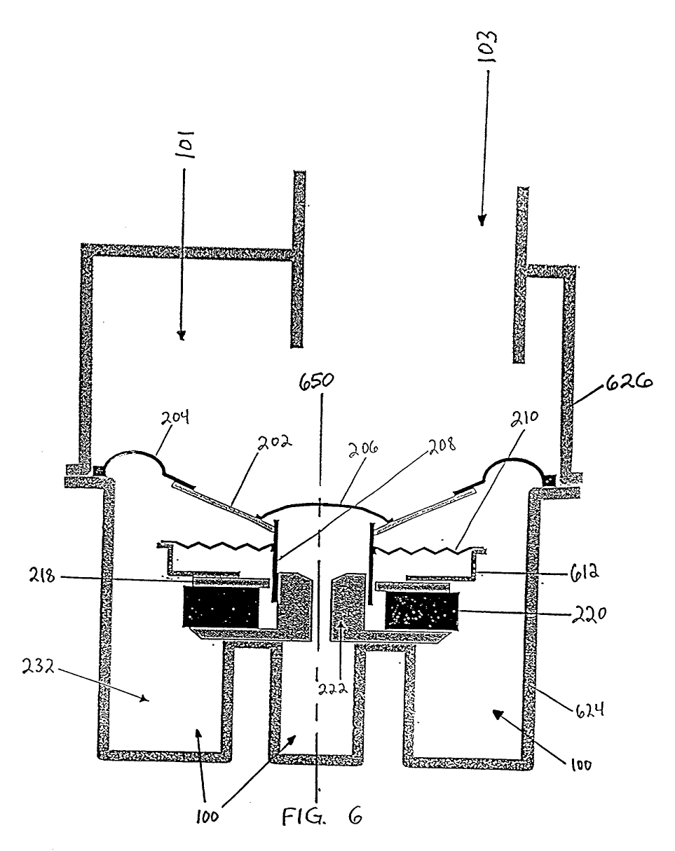

An alternate method of attachment, using a pressure plate mounting means such as that disclosed in U.S. Pat. No. 6,005,957 to Meeks, which is incorporated herein by reference in its entirety, is shown in FIGS. 4 and 5. The embodiment shown in FIG. 4 shows a pressure plate 438, an axial force member 440, an access panel 442, an access panel fastener 444 and an access panel gasket 446 in addition to transducer diaphragm 202, diaphragm suspension 204, dust cap 206, voice coil 208, damper 210, basket 214, enclosure 224, rear air cavity 232, and a motor structure comprising front ring 218, magnet 220, and pole piece 222. The method of attachment disclosed in U.S. Pat. No. 6,005,957 involves creating and storing an axial compression force applied from enclosure 224 to front ring 218, magnet 220, and pole piece 222 via axial force member 440 and pressure plate 438, as shown in FIG. 4. The system is sealed by an integrated gasket-suspension 504, as shown in FIG. 5. This method eliminates the requirement that flange 316 provide sufficient surface area for fasteners 234, but presents additional design constraints and disadvantages. First, enclosure 224 must wrap around the flange to provide an interior surface which accepts axial force member 440, thereby adding volume by increasing the radial dimensions of enclosure 224. Second, axial force member 440 and pressure plate 438 occupy space inside enclosure 224 which could otherwise be used for acoustic air volume. Consequently, the length in the axial direction must be accordingly increased to compensate. Furthermore, enclosure 224 must have access panel 442, which allows the remaining elements to be inserted into place and the axial force member 440 to be pre-loaded during assembly. Access panel 442 is required to have adequate surface area for acoustic sealing and mechanical attachment. This access panel increases the overall size.

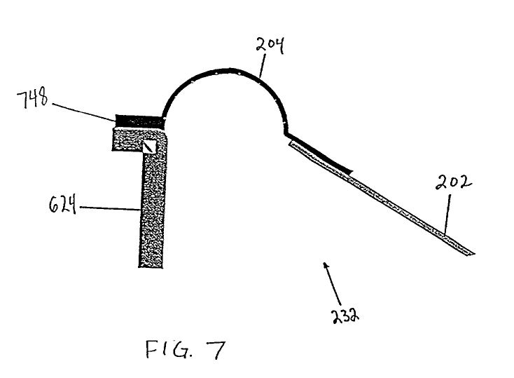

The present invention addresses the shortcomings of these previous designs by combining the functions of the basket and rear enclosure into a single part. FIGS. 6 and 7 illustrate one embodiment of the present invention. The embodiment shown in FIG. 6 incorporates an integrated basket-enclosure 624, a front enclosure 626 and a spider ring 612, and further includes sealed chamber 100, vented chamber 101, passive radiating port 103, rear air cavity 232 and a driver comprising diaphragm 202; diaphragm suspension 204; dust cap 206; voice coil 208; damper 210; and a motor structure comprised of front ring 218, magnet 220, and pole piece 222.

This method of construction allows the size of the enclosure to be reduced. Again, the first dimension to be discussed will be the maximum radial breadth from the axis of loudspeaker motion 650 as shown in FIG. 6. The key to reducing this dimension is reducing the amount of functionality required outside of the diaphragm area. With the present invention, securing the heavy motor structure, which includes front ring 218, magnet 220 and pole piece 222, with respect to integrated basket-enclosure 624 is a function that has been moved from flange 316 of basket 214 as shown in FIGS. 2 and 3, to the rear of integrated basket-enclosure 624 as shown in FIG. 6. In the embodiment of the present invention shown in FIG. 6, pole piece 222 rests on top of raised portions 625 of integrated basket-enclosure 624. Thus, in this embodiment, integrated basket-enclosure 624 directly supports the weight of front ring 218, magnet 220 and pole piece 222.

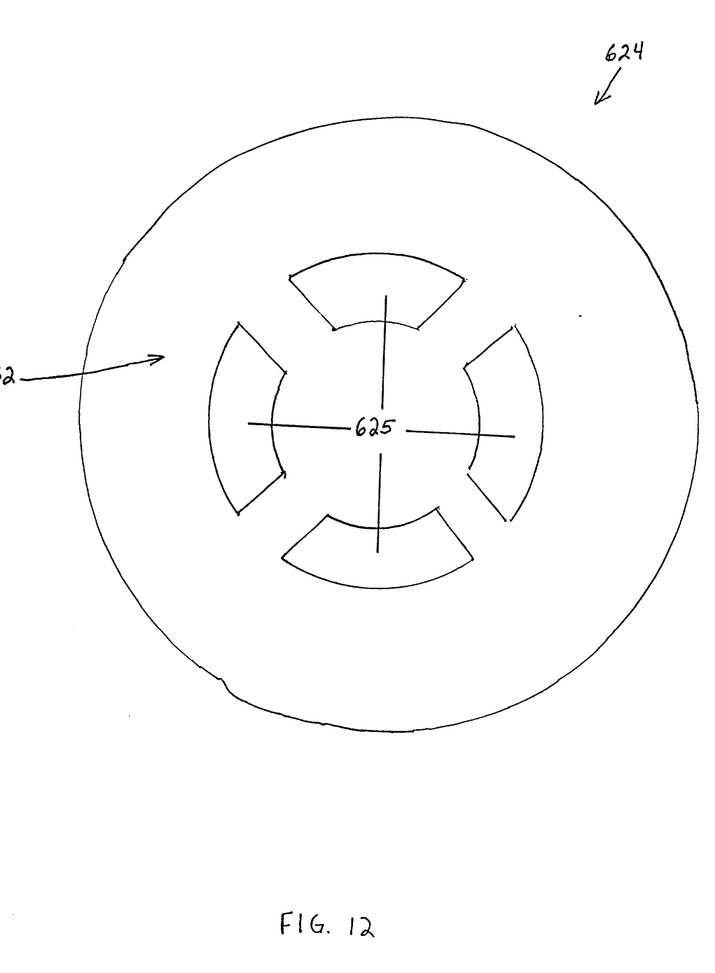

Having the motor structure rest on raised portions 625 does not separate rear air cavity 232 into three distinct areas. This is illustrated more clearly in FIG. 12, which is a bottom view of the embodiment shown in FIG. 6. Integrated basket-enclosure 624 may have a plurality of raised portions. When the motor structure is resting on top of raised portions 625 of integrated basket-enclosure 624, air may still flow between raised portions 625, resulting in a unitary rear air cavity 232. The embodiment illustrated in FIG. 12 shows four discrete raised portions 625 of integrated basket-enclosure 624. Alternatively, any number of raised portions of any shape and size may be used, as would be apparent to one skilled in the relevant art.

Furthermore, in the embodiment shown in FIGS. 6 and 7, diaphragm suspension 204 is directly attached to integrated basket-enclosure 624. As shown in FIG. 7, attachment and sealing is accomplished with an adhesive 748 in lieu of a bulky compression gasket feature. Adhesive 748 may be glue, cement, or any other adhesive as would be apparent to one skilled in the relevant art. In a preferred embodiment, adhesive 748 may be a thin adhesive ring. This adhesive ring could potentially be thinner than a compression gasket seal.

Front enclosure 626 may be attached to integrated basket-enclosure 624 by a means of attachment such as glue, cement, adhesives, screws, rivets, nails, or any similar means of attachment as would be apparent to one skilled in the relevant art. In a preferred embodiment, front enclosure may be screw fastened to integrated basket-enclosure 624.

Another reason this construction design allows the size of the loudspeaker enclosure to be reduced in size is that all parts which in previous systems mechanically linked the motor structure to the enclosure, such as basket 214 shown in FIGS. 2 and 3, and pressure plate 428 and axial force member 440 shown in FIGS. 4 and 5, have been removed in the embodiment shown in FIGS. 6 and 7, and that volume is now made available for acoustic air volume. This allows the dimension of the enclosure in the direction of the loudspeaker axis of motion to be likewise reduced while maintaining the same acoustic air volume.

Of even greater significance, the present invention also presents a thermal advantage, resulting in better durability. With the motor structure directly connected to integrated basket-enclosure 624, there is a direct conduction path between the hottest parts of the loudspeaker (front ring 218, magnet 220 and pole piece 222) and a potentially effective heat sink (integrated basket-enclosure 624). In a preferred embodiment, integrated basket-enclosure 624 may be cast in one piece from aluminum or magnesium, which are good conductors of heat and excellent choices for the molding processes which might be required to facilitate the integrated basket-enclosure part geometry. This new method of rapid heat removal will allow the system to function without failure at higher drive levels.

From a mechanical perspective this new design has the distinct advantage of directly mounting the heaviest parts (front ring 218, magnet 220 and pole piece 222) directly to integrated basket-enclosure 624 instead of allowing them to be suspended away from the enclosure wall via a mechanical framework (such as basket 214). This heavy part also happens to experience a significant amount of mechanical vibration, as it is truly a mechanical motor. Non-linear motor structure vibration causes the diaphragm to move in a non-linear fashion, reducing efficiency and adding undesirable distortion characteristics. Reducing this vibration is therefore a benefit to overall performance.

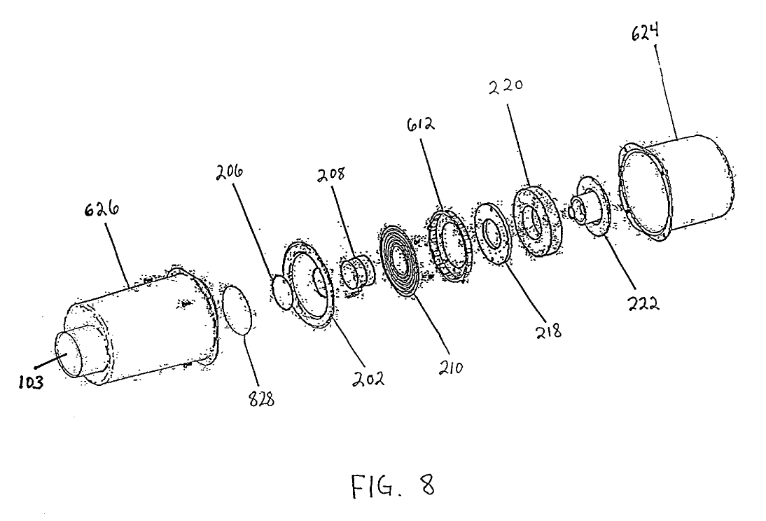

In an alternate embodiment, the integrated basket-enclosure design of the present invention may include a port grill 828 which attaches to front enclosure 626 as shown in FIG. 8.

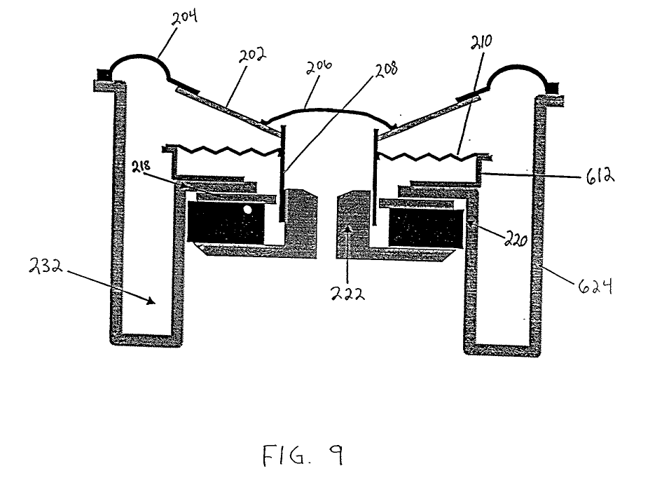

FIG. 9 shows an alternate embodiment of the present invention, wherein the motor structure is mounted to the exterior of an integrated basket-enclosure 924. Spider ring 612 and a motor structure including front ring 222, magnet 220, and pole piece 218 may be attached to integrated basket-enclosure 924 by a means of attachment such as glue, cement, adhesives, screws, rivets, nails, or any similar means of attachment as would be apparent to one skilled in the relevant art. The embodiment shown in FIG. 9 reduces the amount of structure located inside integrated basket-enclosure 924, allowing the volume of integrated basket-enclosure 924 to be reduced. The embodiment shown in FIG. 9 further enhances heat dissipation by moving the hot parts (i.e. the motor structure) to the exterior, where natural and forced convection will draw heat directly to the outside air.

While various embodiments of the present invention have been described above, it should be understood that they have been presented by way of example only, and not limitation. Thus, the breadth and scope of the present invention should not be limited by any of the above-described exemplary embodiments, but should be defined only in accordance with the following claims and their equivalents. Additionally, all references cited herein, including journal articles or abstracts, published or corresponding U.S. or foreign patent applications, issued U.S. or foreign patents, or any other references, are each entirely incorporated by reference herein, including all data, tables, figures, and text presented in the cited references.

The foregoing description of the specific embodiments will so fully reveal the general nature of the invention that others can, by applying knowledge within the skill of the art (including the contents of the references cited herein), readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance presented herein, in combination with the knowledge of one of ordinary skill in the art.

What is claimed is:

1. A loudspeaker enclosure system comprising:
an integrated basket-enclosure having a surface;
a driver comprising a diaphragm and a motor structure, wherein said motor structure abuts said surface of said integrated basket-enclosure.

2. The system of claim 1, said driver further comprising a diaphragm suspension, wherein said diaphragm suspension is directly connected with said integrated basket-enclosure.

3. The system of claim 2, wherein said diaphragm suspension is directly connected with said integrated basket-enclosure by an adhesive.

4. The system of claim 3, wherein said adhesive is an adhesive ring.

5. The system of claim 1, wherein said motor structure comprises a front ring, a magnet, and a pole piece.

6. The system of claim 1, wherein said surface is an outside surface, and said motor structure abuts said outside surface of said integrated basket-enclosure.
